(19) United States
(12) Patent Application Publication
(10) Pub. No.: US 2008/0061309 A1
(43) Pub. Date: Mar. 13, 2008

(54) Semiconductor device with under-filled heat extractor

(76) Inventors: Young Sir Chung, Chandler, AZ (US); Robert W. Baird, Gilbert, AZ (US)

Correspondence Address: INGRASSIA FISHER & LORENZ, P.C. (FS), 7150 E. CAMELBACK ROAD, SUITE 325, SCOTTSDALE, AZ, 85251, US

(21) Appl. No.: 11/490,922

(22) Filed: Jul. 21, 2006

(51) Int. Cl. H01L 33/00

(52) U.S. Cl. 257/98

(57) ABSTRACT

Structure (40, 61-13, 61-15, 61-18, 61-19) and method (60-5 . . . 60-19, 100, 200) are provided for a semiconductor device (40, 61-13, 61-15, 61-18, 61-19) with under-filled heat extractor(s) (46, 46′, 78, 78′). The device (40, 61-13, 61-15, 61-18, 61-19) comprises a substrate (48, 72) with upper (37) and lower (63, 73) surfaces. A semiconductor (38, 72) is located proximate the upper surface (37) with a device region (26) therein. One or more cavities (67, 77) underlying the device region (26) are etched in the substrate (48, 72) from the lower surface (63, 73). A higher thermal conductivity material (68) versus the substrate (48, 72) fills the one or more cavities (67) and has an exposed surface (69, 69′, 79, 79′) underlying the device region (26) at or beyond the lower surface (63, 73). This provides the under-filled heat extractor(s) (46, 46′, 78, 78′). A composite substrate (48) is preferred, having a first semiconductor (38) extending to the upper surface (37) containing the device region (26), a second semiconductor (42) extending to the lower surface (63) and an insulating layer (36) therebetween, wherein the one or more cavities (67) extend from the lower surface (63) to the insulating layer (36) and the etch depth (671) is self limiting.

### TECHNICAL FIELD

The present invention generally relates to semiconductor devices and methods, and more particularly relates to semiconductor devices and methods wherein one or more under-lying heat extraction regions are provided.

### BACKGROUND

In the electronic arts, performance is often limited by the amount of heat that can be extracted from electronic devices or circuits. This is especially true in connection with semiconductor devices and circuits since most are temperature sensitive, that is, their properties and operating conditions often change as their temperature increases. Thus, there is a need to efficiently extract heat from such devices and circuits. For this reason, fans, heat sinks and other cooling mechanisms are often added to semiconductor devices and circuits to carry away the heat being dissipated therein. However, even these auxiliary cooling arrangements may not be adequate when cooling is limited by the rate at which heat can flow from the interior of the semiconductor device or circuit where it is being generated to the external leadframe or package that is coupled to the cooling system. Accordingly, there is a need for improved device structures and methods of fabricating such structures that mitigate or overcome such difficulties.

Accordingly, it is desirable to provide improved device structures and manufacturing methods that permits more effective heat extraction from the device regions wherein thermal energy is produced.

### BRIEF DESCRIPTION OF THE DRAWINGS

The present invention will hereinafter be described in conjunction with the following drawing figures, wherein like numerals denote like elements, and

FIGS. 1-2 are simplified schematic partial cross-sectional views of prior art semiconductor devices illustrating how heat flows from the interior of the device to a supporting lead frame where such heat can be extracted;

FIG. 3 is a simplified schematic partial cross-section view of a semiconductor device generally analogous to the device of FIG. 2, but according to an embodiment of the present invention, illustrating how heat can be extracted more effectively from the interior of the device;

FIG. 4 is a plot of temperature in degrees Celsius versus time in milliseconds, comparing the thermal response of the devices illustrated in FIGS. 1-3 when subjected to a test power pulse;

FIGS. 5-13 show simplified schematic partial cross-sectional views of devices analogous to the device of FIG. 3 at different stages of manufacture according to further embodiments of the present invention;

FIGS. 14-15 show simplified schematic partial cross-sectional views of devices analogous to the device of FIG. 3 at different stages of manufacture according to still further embodiments of the present invention;

FIGS. 16-19 show simplified schematic partial cross-sectional views illustrating further embodiments of the present invention applicable to improving the thermal performance of devices of the type illustrated in FIG. 1; and

FIGS. 20-21 show simplified schematic flow charts illustrating methods of the present invention according to yet further embodiments thereof.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

For simplicity and clarity of illustration, the drawing figures illustrate the general manner of construction, and descriptions and details of well-known features and techniques may be omitted to avoid unnecessarily obscuring the invention. Additionally, elements in the drawings figures are not necessarily drawn to scale. For example, the dimensions of some of the elements or regions in some of the figures may be exaggerated relative to other elements or regions of the same or other figures to help improve understanding of embodiments of the invention

The terms “first,” “second,” “third,” “fourth” and the like in the description and the claims, if any, may be used for distinguishing among similar elements and not necessarily for describing a particular sequential or chronological order. It is to be understood that the terms so used are interchangeable under appropriate circumstances such that the embodiments of the invention described herein are, for example, capable of use or arrangement in sequences other than those illustrated or otherwise described herein. Furthermore, the terms “comprise,” “include,” “have” and any variations thereof, are intended to cover non-exclusive inclusions, such that a process, method, article, or apparatus that comprises a list of elements is not necessarily limited to those elements, but may include other elements not expressly listed or inherent to such process, method, article, or apparatus. The term “coupled,” as used herein, is defined as directly or indirectly connected in an electrical or non-electrical manner.

For convenience of explanation and not intended to be limiting, the present invention is described for transistors and other electronic devices being formed using silicon semiconductor material, but this is not essential and the principles taught herein apply to a wide variety of semiconductor materials. Non-limiting examples of other suitable semiconductor materials are SiC, AlGaN, diamond, and various other type IV, III-V and II-VI compounds and mixtures thereof and organic semiconductors. Accordingly, while silicon in single crystal, polycrystalline or amorphous form is identified as a suitable and exemplary semiconductor material, and silicon oxide and silicon nitride are identified as suitable and exemplary dielectrics and insulators, the present invention is not limited thereto.

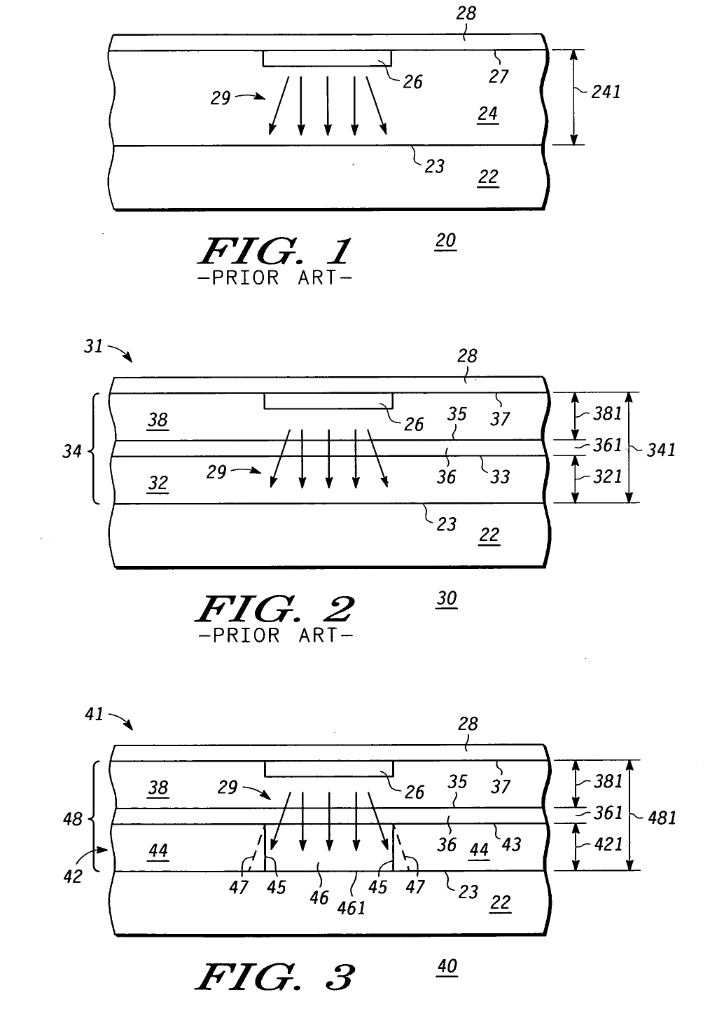

FIGS. 1-2 are simplified schematic partial cross-sectional views of prior art semiconductor devices 20, 30 illustrating how thermal energy 29 flows from device region 26 in the interior of device 20, 30 to supporting heat sink or lead frame 22 where thermal energy 29 can be extracted. Device region 26 represents any type of integrated device or portion of a device within which thermal energy is generated during operation of the device and/or the circuit of which device 20, 30 is a part. Thus, device region 26 maybe a bipolar device region, an field effect device region, an electro-optical device region, a diffused or surface resistor region or any other type of integrated structure or portion thereof that dissipates heat (thermal energy) during operation. The present invention does not depend upon what type of device or portion thereof is present in device region 26. As used herein, the words “device region” are intended to include an entire device or any portion thereof in which thermal energy is dissipated.

In FIG. 1, device 20 shows device region 26 formed in monolithic semiconductor substrate (e.g., Si) 24 of thickness 241. Persons of skill in the art will understand that a single wafer, integrated circuit or other electronic assembly may have multiple regions 26 located therein even though only one such regions is shown herein. Layer 28 overlying upper surface 27 of substrate 24 and device region 26 represents the interconnection and passivation layers commonly found in connection with device region 26. The particular nature of interconnection and passivation layer 28 is not relevant to the present invention. In device 20, thermal energy 29 generated in device region 26 flows through substrate 24 toward upper surface 23 of heatsink 22. Heatsink 22 can be, for example and not intended to be limiting, a leadframe or other package element, with surface 23 on which substrate 24 is mounted. For convenience of description, the word “heatsink” as used herein is intended to include leadframes and any other types of packaging element which provide heat extraction from electronic devices. Such elements may have other functions as well. Thermal energy 29 transferred to heatsink 22 is extracted therefrom using techniques well known in the art. In general, unless another heatsink (not shown) is installed on interconnection and passivation layer 28, thermal energy 29 flowing through substrate 24 to heatsink 22 is the principal pathway by which energy dissipated in device region 26 is extracted from device 20.

Device 30 of FIG. 2 differs from device 20 of FIG. 1 in that composite substrate 34 replaces substantially homogenous substrate 24. The same reference numbers are used to identify similar regions in devices 20, 30 and the discussion thereof is incorporated herein by reference. Composite substrate 34 of thickness 341 comprises second portion 32 conveniently of semiconductor (e.g., Si) of thickness 321, layer 36 of an electrical insulator (e.g., SiO₂) of thickness 361, and first portion 38 also conveniently of semiconductor (e.g., Si) of thickness 381. Device region 26 analogous to device region 26 of device 20 is formed in first portion 38. Device 30 is typically referred to as a semiconductor-on-insulator (SOI) structure or device. Thermal energy 29 generated in device region 26 of device 30 of FIG. 2 flows through first portion 38, electrical insulator 36 and second portion 32 in order to reach heatsink 22. The presence of insulating layer 36 tends to substantially increase the thermal impedance of device 30 compared to device 20, but SOI structure 31 of device 30 can offer performance advantages compared to homogeneous device 20 of FIG. 1 due to its reduced junction parasitic components and enhanced electrical isolation performance. Such SOI devices are widely used, especially in small signal application where power dissipation is not a significant concern. However, for high power device applications, the poorer thermal performance of such SOI structures can become a critical limitation.

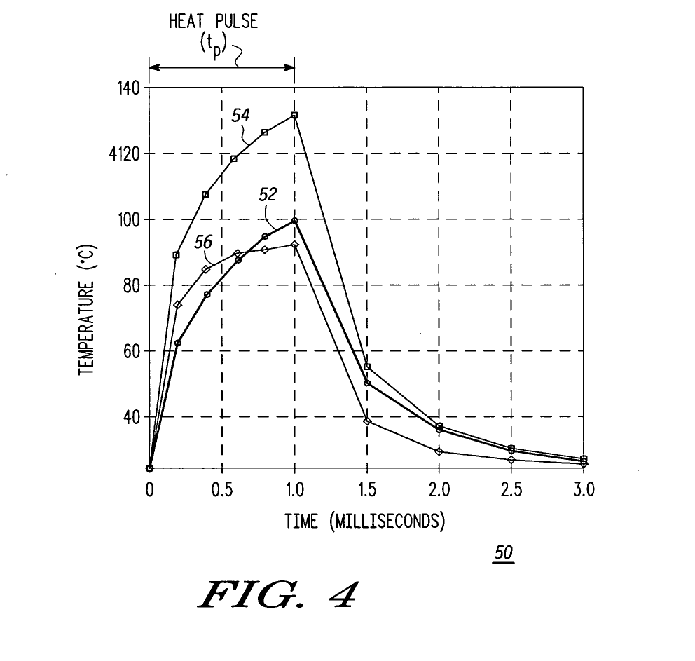

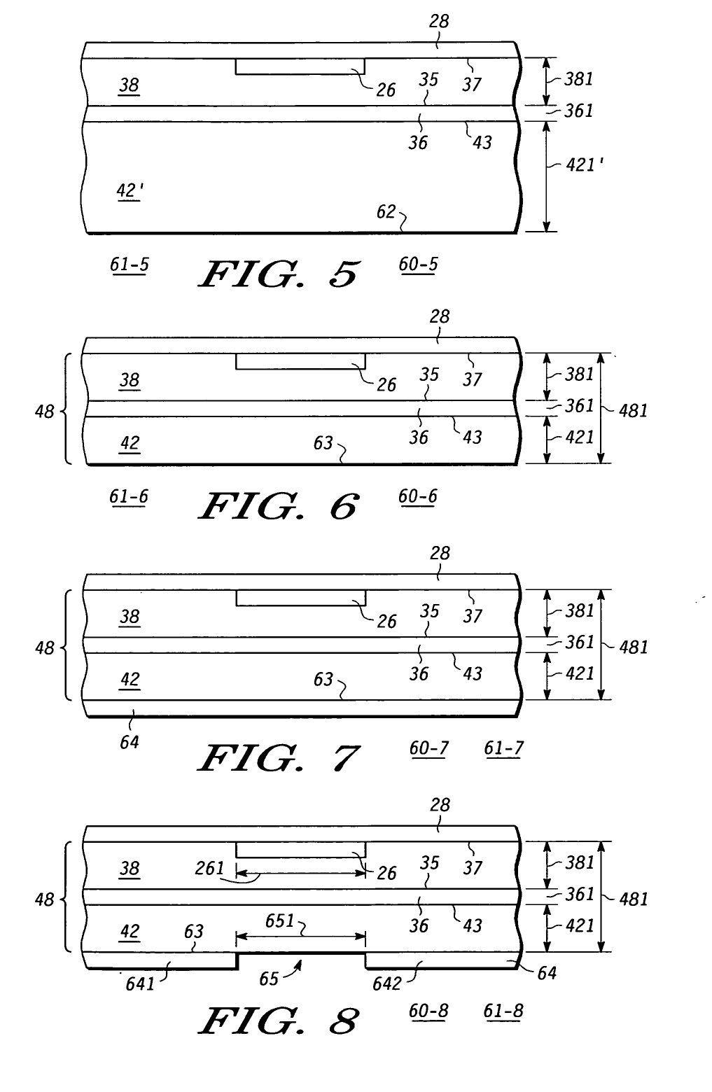

FIG. 3 is a simplified schematic partial cross-section view of semiconductor device 40 generally analogous to SOI device 30 of FIG. 2, but according to the present invention, illustrating how thermal energy 29 can be extracted more effectively from interior device region 26. The same reference numbers are used to identify similar regions in devices 20, 30, 40 and the discussion thereof is incorporated herein by reference. In device 40, composite substrate 48 of thickness 481 comprises second portion 42 of thickness 421, insulating layer 36 (e.g., of SiO₂) of thickness 361 and first portion 38 (e.g., of Si) of thickness 381 in which device region 26 is located, thereby forming SOI structure 41 electrically analogous to SOI structure 31 of device 30. Second portion 42 has regions 44 (e.g., of Si) lying generally laterally outside device region 26 and high thermal conductivity region 46 (e.g., of Cu) located generally underneath device region 26. Insulating layer 36 separates both regions 44 and 46 from first portion 38 in which device regions 26 is formed. Regions 44 are generally analogous to second portion 32 of device 30 and conveniently formed using the same materials (e.g., Si). High thermal conductivity region 46 extends from insulating layer 36 to interface 461 in intimate contact with surface 23 of heatsink 22. High thermal conductivity region 46 may have substantially straight sidewalls 45 or inclined sidewalls 47, depending upon the details of the fabrication process chosen by the designer (e.g., see for example FIGS. 5-13). Either arrangement is useful. High thermal conductivity materials, as for example and not intended to be limiting, copper, aluminum, silver, gold, other metals and various alloys thereof are suitable for region 46. Copper is preferred for region 46. For the same layer thickness 321 and 421, all that is required in order for device 40 of FIG. 3 to provide improved thermal performance compared to device 30 of FIG. 2, is that region 46 have a thermal conductivity larger than that of the material of portion 32. It is desirable that region 46 be located substantially underneath device region 26 where thermal energy 29 originates so as to minimize the thermal path length between region 26 and heatsink 22. Accordingly, region 46 is referred to as an “under-filled” heat extractor. Making region 46 of a material with a higher thermal conductivity than what would be obtained using semiconductor or other comparatively lower thermal conductivity substrate, improves the thermal response of device 40 compared to device 30. As will be seen, it can also provide thermal performance equal to or better than that of device 20.

FIG. 4 is shows plot 50 of temperature in degrees Celsius versus time in milliseconds, comparing the calculated thermal response of devices 20, 30, 40 illustrated in FIGS. 1-3 and having the same device region 26 and the substrate thicknesses 241, 341, 481 between surface 27, 37 and heatsink 22, when subjected to a power pulse of duration tₚ. In all three cases, portions or regions 24, 32, 38, 44 were assumed to be single crystal silicon, insulating layer 36 was assumed to be silicon dioxide and high thermal conductivity region 46 was assumed to be copper of substantially the same lateral dimensions as device region 26. For purposes of this analysis, it was assumed that the power pulse was being dissipated substantially uniformly in region 26 and the mean temperature of region 26 was calculated as a function of time in response to such power pulse, taking into account the thermal dissipation to heatsink 22 through substrates 24, 34, 48. Trace 52 shows the thermal response of device 20 of FIG. 1, trace 54 shows the thermal response of device 30 of FIG. 2 and trace 56 shows the thermal response of device 40 of FIG. 3. As mentioned earlier, introducing insulating layer 36 substantially degrades the thermal performance of device 30 compared to device 20, that is, the peak temperature is about 130 degrees Celsius for SOI device 30 as compared to about 100 degrees Celsius for device 20 in response to the same power pulse. Trace 56 illustrates the thermal response of SOI device 40 of FIG. 3. It will be noted that the peak temperature is about 90 degrees Celsius, significantly lower than that obtained with either prior art arrangement of devices 20 or 30. The peak temperature associated with device 40 of the present invention is substantially lower because thermal energy 29 is being more effectively extracted from device 40 than from devices 20, 30. Thus, the embodiment shown provides a significant improvement in thermal performance. This means that for the same device operating conditions, device 40 will have lower operating temperature, or for the same operating temperature, device 40 can handle larger amounts of power, or a combination thereof. These results are highly desirable and are obtained without any increase in device area, a critical factor in device cost. While FIG. 3, illustrates a single device or portion of a device according to an embodiment of the present invention, persons of skill in the art will understand based on the teachings herein that many devices or portions of a device can be fabricated at the same time on the same substrate and electrically coupled to form one or more devices or an integrated circuit, wherein each device region 26 dissipating significant power has under-filled region 46 of high thermal conductivity material that can be thermally coupled to heatsink 22 (or equivalent) at interface 461. Further, while FIGS. 5-19 illustrate formation of a single under-filled cavity beneath device region 26, this is merely for convenience of explanation and not intended to be limiting. Multiple cavities may also be formed under device region 26. A number of smaller cavities can be formed in the place of a single larger cavity. Such multiple cavities may be formed and filled in the same manner as described herein for a single cavity. This approach may be desirable where a large area thermal energy source is involved. Thus, the embodiments described herein are applicable to both single and multiple under-filled cavity arrangements. For convenience of explanation, formation of a single cavity is described, but persons of skill in the art will understand that more than one cavity may be formed and under-filled beneath any particular device region using the procedures described herein.

FIGS. 5-13 show simplified schematic partial cross-sectional views of devices analogous to SOI device 40 of FIG. 3 at different stages 60-5 through 60-13 of manufacture according to further embodiments of the present invention. Referring now to manufacturing stage 60-5 of FIG. 5, substrate 42′ of thickness 421′ and with upper surface 43 and lower surface 62 is provided. Substrate 42′ is conveniently of semiconductor, as for example and not intended to be limiting, a single crystal silicon wafer, but this is not essential and many other types of materials and structures may also be used. In general, substrate 42′ provides mechanical support for device 40 during fabrication thereof and does not otherwise participate in the electrical performance of device 40, except perhaps as a ground plane or the like. Hence a wide variety of materials may be used for substrate 42′, but single crystal silicon is convenient. Layer 36 of thickness 361 and having upper surface 35 is formed on upper surface 43 of substrate 42′. First portion 38 is formed on upper surface 35 of layer 36. Device region 26 is formed in first portion 38. First portion 38 is of semiconductor, preferably silicon but, as noted earlier in connection with the discussion of FIGS. 2-3, portion 38 may be of a wide variety of semiconductor materials depending upon the needs of the device designer and the type of the device being formed in device region 26. Interconnection and passivation layer 28 is desirably but not essentially formed over surface 37 of first portion 38 and device region 26, its exact nature depending upon the nature of device region 26 and the semiconductor material chosen for first portion 38. Thickness 421′ is chosen to provide sufficient mechanical strength during the processing needed to form layer 36, first portion 38, device region 26 and optional interconnection and passivation layer 28. Persons of skill in the art will understand that thickness 421′ will generally depend on the size (e.g., diameter) of substrate 42′ being used for manufacturing stage 60-5 and the particular processing tools they intend to use. Formation of SOI structure 61-5 shown in manufacturing stage 60-5 may be accomplished using techniques well known in the art. Thickness 361 is usefully in the range of about 0.05 to 20.0 micrometers, more conveniently about 0.1 to 5.0 micrometers and preferably about 0.2 to 1.0 micrometers, however, smaller or larger thicknesses can also be used, depending upon the needs of the designer. Thickness 381 is usefully in the range of about 0.1 to 100 micrometers, more conveniently about 0.5 to 50 micrometers and preferably about 1 to 10 micrometers, however, smaller or larger thicknesses can also be used, depending upon the needs of the designer, but sufficient to contain device region 26.

In manufacturing stage 60-6 of FIG. 6, substrate 42′ is lapped or otherwise reduced in thickness so as to provide second portion 42 of substantially finished thickness 421. Thickness 421 is usefully in the range of about 100 to 1000 micrometers, more conveniently about 300 to 700 micrometers and preferably about 400 to 600 micrometers, however, smaller or larger thicknesses can also be used, depending upon the needs of the designer. Second portion 42, layer 36 and first portion 38 make up composite substrate 48 of combined thickness 481 for SOI structure 61-6 having device region 26 therein. In manufacturing stage 60-7, mask layer 64 is applied to lower surface 63 of second portion 42. Mask layer 64 is conveniently of silicon nitride or silicon oxide but organic materials such as photo-resist or poly-methyl-methacrylate (PMM) or spun-on glasses or other common mask materials may also be used. The thickness of mask layer 64 will depend upon the type of material chosen for mask layer 64. Structure 61-7 results. In manufacturing stage 60-8, opening 65 is formed in mask layer 64, substantially beneath device region 26, leaving portions 641-642 substantially laterally surrounding opening 65. Opening 65 is located beneath or under device region 26 by any convenient double-sided wafer alignment technique. Great alignment precision is not usually required, since the lateral dimensions of device region 26 whose power dissipation makes it desirable to provide under-fill region 64 are generally comparatively large and therefore lateral dimension 651 of opening 65 can also be comparatively large. It is generally desirable that lateral dimensions 651 of opening 65 is at least equal to dimension 261 of device region 26 where significant power is being dissipated, but larger and smaller dimensions can also be used. Structure 61-8 results.

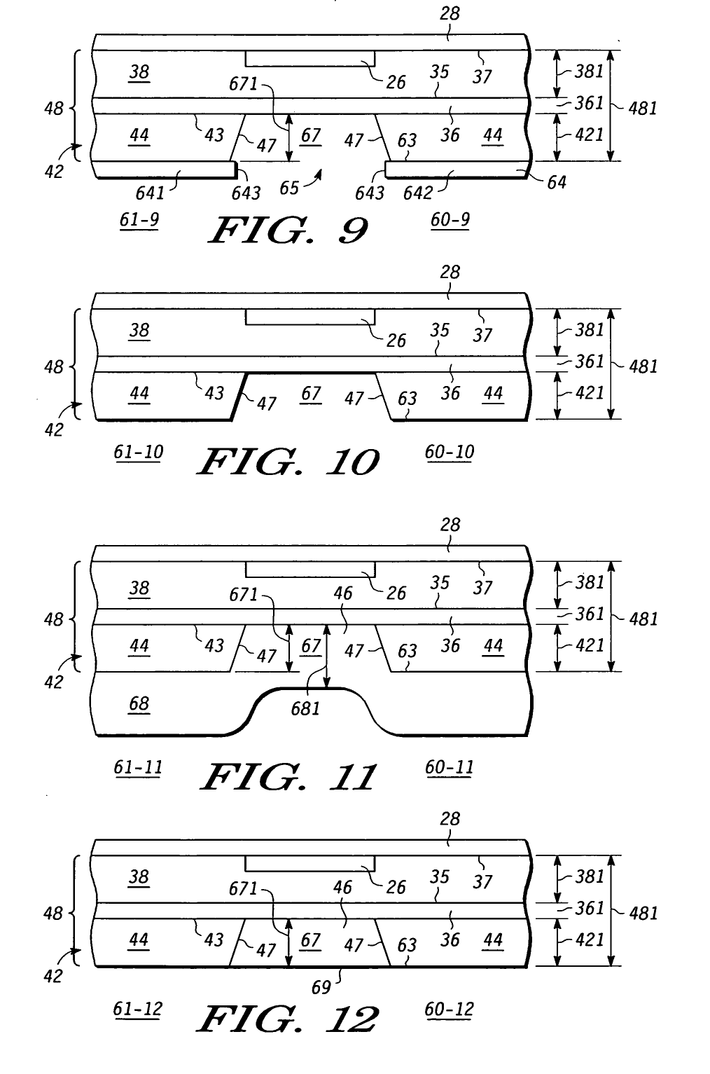

In manufacturing stage 60-9 of FIG. 9, second portion 42 is etched through mask opening 65 to produce cavity 76 of depth 671 with sidewalls 47 separating regions 44 of second portion 42. If a generally isotropic etching procedure is used, as for example wet etching, then sidewalls 47 will slope and slightly undercut edges 643 of mask 64. That is the situation shown in structure 61-9 following manufacturing stage 60-9. However, if an anisotropic etch is used, that is, an etching procedure that etches vertically more rapidly than horizontally, then approximately straight sidewalls such as for example sidewalls 45 of FIG. 3 will result. Either arrangement is useful. Etching is not especially critical since an etchant that selectively etches the semiconductor or other material of second portion 42 and does not substantially etch insulating layer 36 can be used and is desirable. In this manner, etching cavity 67 through mask opening 65 is substantially self limiting in depth. Structure 61-9 results. In manufacturing stage 60-10, remaining portions 641-642 of mask 64 are removed, thereby providing structure 61-10. It is desirable that the etchant or solvent used to remove remaining portions 641-642 not significantly attack the material of remaining regions 44 of second portion 42 or insulating layer 36. When mask layer 64 is of photoresist this is easily accomplished. Silicon nitride is also suitable for mask layer 64 since it is substantially selectively etchable with respect to, for example, silicon oxide of layer 36 and silicon of second portion 42. Persons of skill in the art will understand that other combinations of materials may also be used.

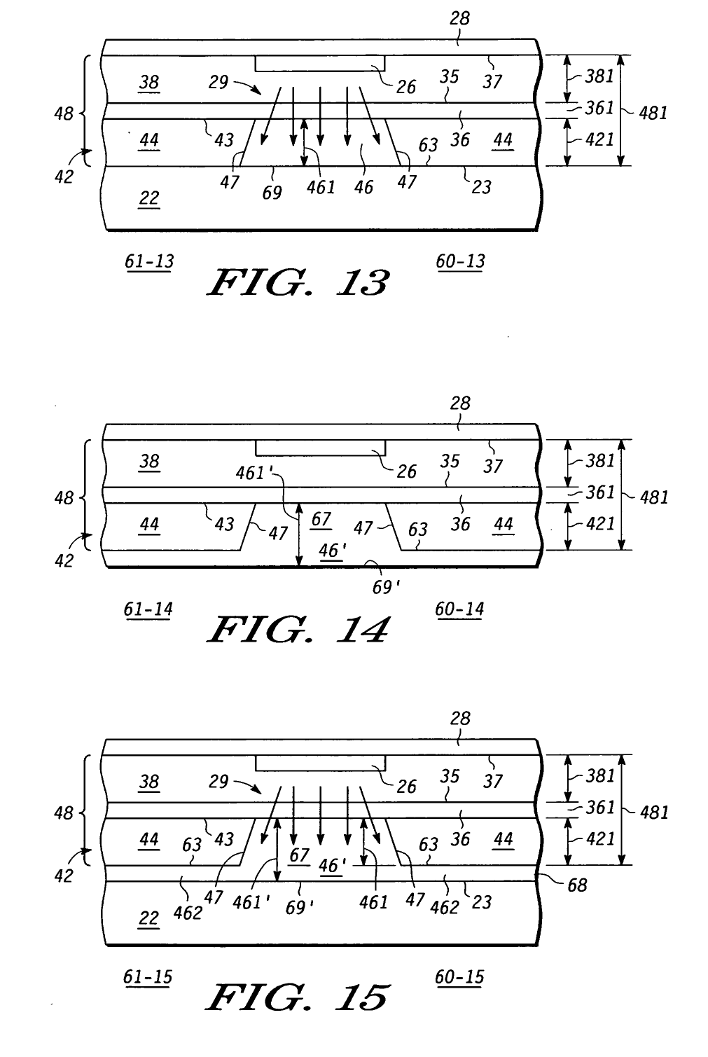

In manufacturing stage 60-11 of FIG. 11, cavity 67 is filled by depositing highly thermally conductive material (e.g., copper) layer 68 therein. Electrochemical plating is a convenient method of depositing high thermal conductive materials such as for example copper, but other techniques and materials may also be used. Thickness 681 of layer 68 in cavity 67 needs to be equal or greater than thickness 421 and/or cavity depth 671 so that cavity 67 is filled to a level at least equal to surface 63 of regions 44 of second portion 42. Structure 61-11 result. In manufacturing stage 60-12 of FIG. 12, layer 68 is planarized, for example by chemical-mechanical polishing (CMP), a technique widely used in the semiconductor industry, so that finished surface 69 of region 64 of high thermal conductivity material in cavity 67 is, for example and not intended to be limiting, substantially coplanar with surface 63 of adjacent regions 44 of second portion 42. Structure 61-12 results. Manufacturing stage 60-13 of FIG. 13 shows structure 61-12 after attachment to heatsink 22, as depicted in connection with device 40 of FIG. 3. Any convenient die bonding, soldering, gluing or brazing technique may be used for attaching structure 60-12 to heatsink 22, provided that any attachment material has negligible thermal impedance compared to the remainder of substrate 48. Structure 61-13 analogous to device 40 of FIG. 3 results.

While FIG. 12 illustrates the situation where dimension 421 is substantially unchanged by planarizing, and surfaces 63 and 69 are substantially coplanar, this is convenient but not essential. Dimension 421 of manufacturing stage 60-12 may be of any convenient size provided that the finished lower surface 69 of under-filled heatsink substrate 46 is substantially planar and that substrate 48 has sufficient mechanical strength to withstand any remaining manufacturing stages. Thus, dimension 421 of manufacturing stage 60-12 may be smaller than dimension 421 of manufacturing stage 60-11. This can result from continuing the planarizing process beyond the point where surfaces 63 of regions 44 are exposed. Either arrangement is useful. Conversely, it is not necessary that all of layer 68 be completely removed from surfaces 63 of regions 44. This situation is illustrates in alternate manufacturing stage 60-14 of FIG. 14, wherein dimension 461′ of region 46 exceeds thickness 421 (and cavity depth 471) and lower surface 69′ of layer 68 and region 46′ after planarizing, extends beneath both cavity 67 and regions 44. Alternate structure 61-14 results. Either arrangement is useful. Manufacturing stage 60-15 of FIG. 15 shows structure 61-14 after attachment to heatsink 22. Any convenient die bonding, soldering, gluing or brazing technique may be used for attaching structure 61-14 to heatsink 22. Such attachment material should have negligible thermal impedance compared to the remainder of substrate 48. Structure 61-15 results, analogous to device 40 of FIG. 3 with the addition of thin high thermal conductivity material portion 462 extending between surfaces 63 of substrate regions 44 of composite substrate 48 and surface 23 of heatsink 22.

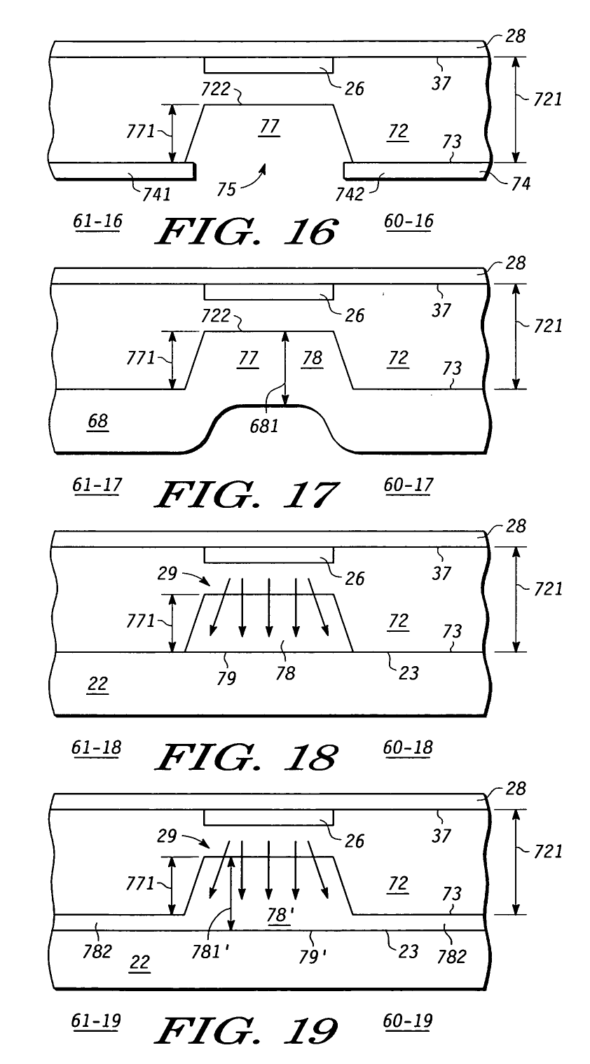

FIGS. 16-19 show simplified schematic partial cross-sectional views illustrating further embodiments of the present invention for alternate manufacturing stages 60-16 through 60-19 applicable to improving the thermal performance of devices of the type illustrated in FIG. 1. Structure 61-16 of FIG. 16 comprises semiconductor substrate 72 (e.g., silicon) of thickness 721, having lower surface 73 and upper surface 37, in which device region 26 has been formed as previously described. Thickness 721 is usefully in the range of about 100 to 1000 micrometers, more conveniently about 300 to 800 micrometers and preferably about 500 to 700 micrometers, however, smaller or larger thicknesses can also be used. Structure 61-16 is equivalent to structure 61-9 but with insulating layer 36 omitted and semiconductor 72 is of a material suitable for the formation of desired device region 26. Mask layer 74 analogous to mask 64 of FIG. 8 has been applied, opening 75 analogous to opening 65 has been formed therein thereby leaving mask portions 741, 742 laterally adjacent mask opening 75, and cavity 77 analogous to cavity 67 has been etched through opening 75. Since insulating layer 36 is not present, depth 771 of cavity 77 can be determined by a timed etch. The exact amount of etching time needed to bring inner surface 772 of cavity 77 within good thermal reach of device region 26 without interfering with the electrical properties of device region 26 will depend upon the material being used for substrate 72, the type of device formed in device region 26 and the type of etchant being used. Persons of skill in the art will understand how to determine the appropriate etching time without undue experimentation. Structure 61-16 results. In manufacturing stage 60-17 of FIG. 17, remaining mask portions 741-742 are removed and cavity 77 filled with high thermal conductivity material 68 of thickness 681 greater than depth 771 in the same manner as described in connection with manufacturing stage 60-11, and then planarized in the same manner as described in connection with manufacturing stage 60-12 or 60-14. This provides under-filled region 78 analogous to under-filled region 64. This structure is then attached to heatsink 22 as shown in manufacturing stages 60-18 or 60-19, to provide structure 61-18 of FIG. 17 or structure 61-19 of FIG. 19. Structure 61-18 results when layer 68 is planarized so as to expose lower surfaces 73 of substrate 72 and structure 61-19 results when layer 68 is planarized without exposing surfaces 73 of substrate 72. Either arrangement is useful. As noted in connection with the discussion of manufacturing stages 60-12 through 60-15, substrate 72 may be thinned during the planarization process wherein surfaces 73 are exposed or high thermal conductivity material 782 may be left on surfaces 73. Either arrangement is useful. The discussion accompanying manufacturing stages 60-8 through 60-15 except for references to layer 36, is incorporated herein by reference.

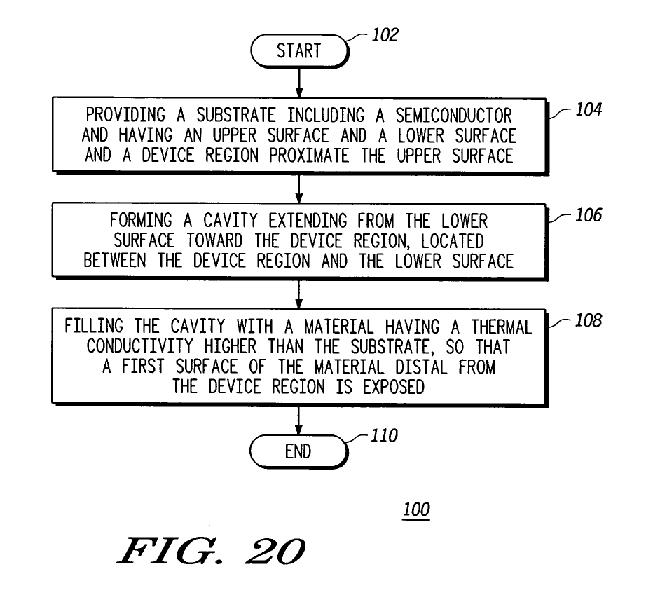

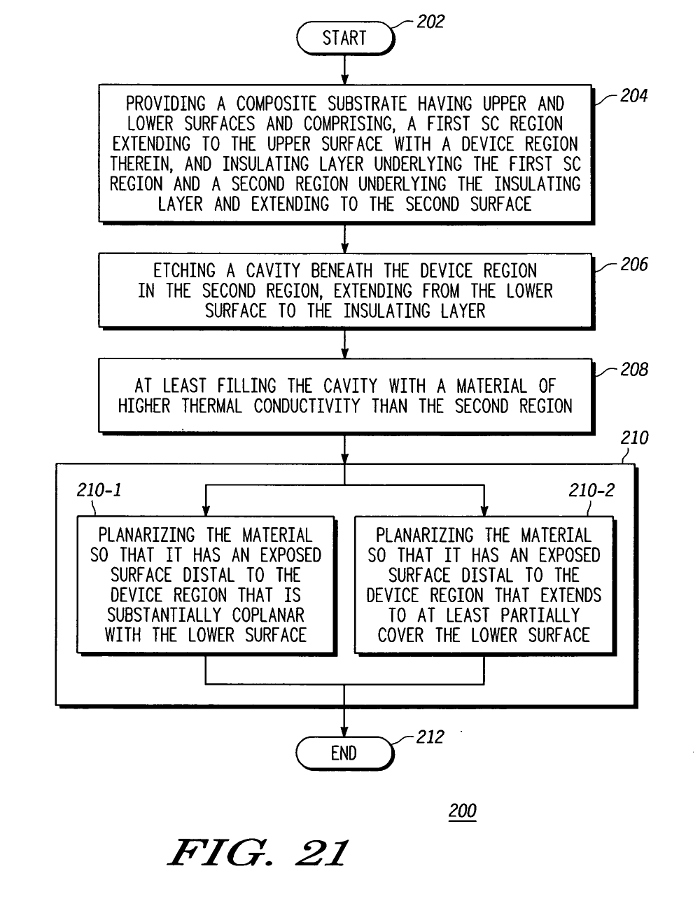

FIGS. 20-21 show simplified schematic flow charts illustrating methods 100, 200 of the present invention according to yet further embodiments thereof. For convenience of description, reference is made, by way of example and not intended to be limiting, to various regions illustrated in FIGS. 5-19. Referring now to FIG. 20, method 100 begins with START 102 and initial step 104 comprising, providing a substrate (e.g., 48, 72) including a semiconductor (e.g., 38, 72) and having an upper surface (e.g., 37) and a lower surface (e.g., 63, 73) and a device region (e.g., 26) proximate the upper surface (e.g., 37). In subsequent method step 106, a cavity (e.g., 67, 77) is formed extending from the lower surface (e.g., 63, 73) toward the device region (e.g., 26), located between the device region (e.g., 26) and the lower surface (e.g., 63, 73). In subsequent method step 108, the cavity (e.g., 67, 77) is filled with a material (e.g., 68) having a thermal conductivity higher than that of the substrate (e.g., 48, 72), so that a first surface (e.g., 69, 69′, 79, 79′) of the material (e.g., 68) distal from the device region (e.g., 26) is exposed, thereby forming a semiconductor device (e.g., 40, 61-13, 61-15, 61-18, 61-19) with an under-filled heat extractor (e.g., 46, 46′, 78, 78′). While FIGS. 3, 13, 15, 18 and 19, show the under-filled heat extractor 69, 69′, 79, 79′ in contact with surface 23 of heatsink 22, this is merely for convenience of explanation and not intended to be limiting. Semiconductor devices according to exemplary embodiments of the present invention, for example and not intended to be limiting, devices 40, 61-13, 61-15, 61-18, 61-19 do not require that heatsink 22 be present, and it is shown merely to indicate how a heatsink may be used in connection with under-filled heat extractors 46, 46, 78, 78′ described herein. Thus, as used herein the term “semiconductor device”, singular or plural, is not intended to require the presence of a heatsink as a part of the semiconductor device or method, and a heatsink, such as heatsink 22, is illustrated merely as a useful but not essential appendage to the devices provided by the structures and methods of the present invention.

Referring now to FIG. 21, method 200 begins with START 202 and initial step 204 comprising, providing a composite substrate (e.g., 48) having upper (e.g., 37) and lower (e.g., 63) surfaces and comprising, a first semiconductor (abbreviated as “SC) region (e.g., 38) extending to the upper surface (e.g., 37) with a device region (e.g., 26) therein, an insulating layer (e.g., 36) underlying the first SC region (e.g., 38) and a second region (e.g., 42) underlying the insulating layer (e.g., 36) and extending to the second surface (e.g., 63). In method step 206, a cavity (e.g., 67) is etched beneath the device region (e.g., 26) in the second region (e.g., 42) extending from the lower surface (e.g., 63) to the insulating layer (e.g., 63). Cavity 67 has for example, depth 671, conveniently of the same size as thickness 421 of second region 42 since insulating layer 36 conveniently acts as a depth etch stop for cavity 67. In filling step 208, a material (e.g., 68) of higher thermal conductivity than the second region (e.g., 42) is applied to at least fill the cavity (e.g., 67). Such material (e.g., 68) may also be applied on the lower surface (e.g., 63), but this is not essential.

If the higher thermal conductivity material (e.g., 68) is also applied on the lower surface (e.g., 63), then in planarization step 210 any excess material lying outside the cavity may be removed, according to either of sub-steps 210-1 or 210-2, depending upon the desires of the device designer. If cavity 67 is merely filled so that no significant excess material is present, then planarization step 210 is not needed. However, in the preferred method, it is convenient to provide some excess material 68 in step 208 so that high thermal conductivity material thickness 681 is slightly greater than cavity depth 671, and the excess material removed in step 210 so that under-filled heat extraction region 46, 46′ may be provided with generally planar lower surface 69, 69′ convenient for removing heat therefrom. In alternate planarization step 210-1, structure 61-11 illustrated in FIG. 11 is planarized, e.g., back-lapped by chemical-mechanical polishing (CMP) so that the exposed surface (e.g., 69) of the material (e.g., 64) filling the cavity (e.g., 67) is substantially coplanar with the lower surface (e.g., 63) of the second region (e.g.,), thereby yielding structure 61-12 illustrated in FIG. 12. With this situation, both lower exposed surface 69 of under-filled heat extractor 46 and lower surfaces 63 of remaining regions 44 of second portion 42 are exposed and substantially coplanar. If it is desired to thin substrate 48, CMP maybe carried on beyond the point where surfaces 63 are initially exposed, thereby reducing thickness 421 and depth 671 by substantially equal amounts.

In alternate planarization method step 210-2, structure 61-11 illustrated in FIG. 11 is also planarized, e.g., back-lapped by chemical-mechanical polishing (CMP), but not all of high thermal conductivity material 68, 462 overlying surfaces 63 of regions 44 of second portion 42 is removed. With this arrangement, residual thickness 461′ of under-filled heat extractor 46′ exceeds cavity depth 461. In this manner, exposed surface 69′ of under-filled heat extractor 46′ is exposed and planarized, which facilitates thermal coupling to an external heatsink. Portions 462 of material 68 are left in place extending beyond and/or at least partially covering surfaces 63 of regions 44 of second portion 42. Structure 61-14 results. Either arrangement is useful.

According to a first embodiment, there is provided a method for forming a semiconductor device with an integral heat extractor, comprising, providing a substrate including a semiconductor and having an upper surface and lower surface and a device region in the semiconductor proximate the upper surface, forming one or more cavities extending from the lower surface toward the device region and located between the device region and the lower surface, and filling the one or more cavities with a material having a thermal conductivity higher than the semiconductor, so that a first surface of the material is exposed, thereby creating the integral heat extractor. According to a further embodiment, the first surface is substantially coplanar with lower surface. According to a still further embodiment, the first surface is substantially parallel to and extends beyond the lower surface. According to a yet further embodiment, the substrate is a composite substrate having a first region extending to the upper surface and containing the semiconductor in which the device region is formed, a dielectric layer underlying the first region and a second region underlying the dielectric layer and extending to the lower surface. According to a still yet further embodiment, the one or more cavities extend from the lower surface to the dielectric layer. According to a yet still further embodiment, forming the one or more cavities comprises etching the second region using an etchant that etches the second region without substantially etching the dielectric layer. According to an additional embodiment, the second region comprises a semiconductor. According to a further additional embodiment, the semiconductor is silicon.

According to a second embodiment, there is provided a method for forming one or more under-filled heat extractors for a semiconductor device region, comprising, providing a substrate having an upper surface, a lower surface and a semiconductor in which the device region is located extending to the upper surface, etching one or more cavities in the substrate from the lower surface underneath the device region, extending part way through the substrate toward the device region, and filling the one or more cavities with a higher thermal conductivity material relative to the substrate so that an exterior surface of the material lies at or beyond the lower surface. According to a further embodiment, filling the one or more cavities comprises, covering the lower surface and the one or more cavities with the material to a thickness at least sufficient to fill the one or more cavities, and removing excess material so that the exterior surface of the material is substantially coplanar with the lower surface. According to a still further embodiment, removing excess material comprises thinning the substrate by also removing part of the substrate at the lower surface. According to a yet further embodiment, filling the one or more cavities comprises, covering the lower surface and the one or more cavities with the material to a thickness more than sufficient to fill the one or more cavities, and removing excess material so that the exterior surface of the material is substantially planar and lies beyond the lower surface. According to a yet still further embodiment, the substrate is a semiconductor extending substantially from the upper to the lower surface. According to a still yet further embodiment, providing a substrate comprises, providing a composite substrate having a first semiconductor region proximate the upper surface containing the device region, a second semiconductor region proximate the lower surface, and an insulating layer located between the first and second semiconductor regions, and etching one or more cavities comprises, etching one or more cavities extending from the lower surface underneath the device region through the second semiconductor region to the insulating layer.

According to a third embodiment, there is provided a semiconductor device including an under-filled heat extractor, comprising, a substrate having an upper surface and a lower surface and a semiconductor located proximate the upper surface with a device region therein, one or more cavities formed in the substrate extending from the lower surface toward the upper surface and underlying the device region, and a higher thermal conductivity material relative to the substrate, filling the one or more cavities and with an exposed surface underlying the device region at or below the lower surface, thereby forming the under-filled heat extractor. According to a further embodiment, the exposed surface is substantially coplanar with the lower surface. According to a still further embodiment, the exposed surface is substantially planar and covers at least part of the lower surface. According to a yet further embodiment, the substrate is a composite substrate with a first semiconductor region extending to the supper surface and containing the device region, a second semiconductor region extending to the lower surface and an insulating layer located between the first and second semiconductor regions, and the one or more cavities extend from the lower surface to the insulating layer. According to a still yet further embodiment, the first and second semiconductor regions comprise silicon and the insulating layer comprises silicon oxide. According to a yet still further embodiment, the higher thermal conductivity material comprises copper, silver, aluminum, gold or other metals having a thermal conductivity larger than the semiconductor.

While at least one exemplary embodiment has been presented in the foregoing detailed description, it should be appreciated that a vast number of variations exist, especially with respect to choices of materials for portions or regions or layers 42, 36, 38, 44, 46, 64, 68, 72, 74, 78, etc., and the detailed fabrication steps used to provide the various intermediate structures illustrated herein in connection with the various manufacturing stages. Further, while silicon semiconductor of various crystalline forms and doping types, and silicon oxide and silicon nitride dielectrics are illustrated, this is merely by way of example and for convenience of description and not limitation. Accordingly, the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements and sequence of steps without departing from the scope of the invention as set forth in the appended claims and the legal equivalents thereof.

What is claimed is:

1. A method for forming a semiconductor device with an integral heat extractor, comprising:
providing a substrate including a semiconductor and having an upper surface and lower surface and a device region in the semiconductor proximate the upper surface;
forming one or more cavities extending from the lower surface toward the device region and located between the device region and the lower surface; and
filling the one or more cavities with a material having a thermal conductivity higher than the semiconductor, so that a first surface of the material is exposed, thereby creating the integral heat extractor.

2. The method of claim 1, wherein the first surface is substantially coplanar with lower surface.

3. The method of claim 1, wherein the first surface is substantially parallel to and extends beyond the lower surface.

4. The method of claim 1, wherein the substrate is a composite substrate having a first region extending to the upper surface and containing the semiconductor in which the device region is formed, a dielectric layer underlying the first region and a second region underlying the dielectric layer and extending to the lower surface.

5. The method of claim 4, wherein the one or more cavities extend from the lower surface to the dielectric layer.

6. The method of claim 5, wherein forming the one or more cavities comprises etching the second region using an etchant that etches the second region without substantially etching the dielectric layer.

7. The method of claim 4, wherein the second region comprises a semiconductor.

8. The method of claim 1, further comprising after the filling step, mounting the semiconductor device on a heat sink with the integral heat extractor in thermal contact with the heatsink.

9. A method for forming one or more under-filled heat extractors for a semiconductor device region, comprising:
providing a substrate having an upper surface, a lower surface and a semiconductor in which the device region is located extending to the upper surface;
etching one or more cavities in the substrate from the lower surface underneath the device region, extending part way through the substrate toward the device region; and
filling the one or more cavities with a higher thermal conductivity material relative to the substrate so that an exterior surface of the material lies at or beyond the lower surface.

10. The method of claim 9, wherein filling the one or more cavities comprises:
covering the lower surface and the one or more cavities with the material to a thickness at least sufficient to fill the one or more cavities; and
removing excess material so that the exterior surface of the material is substantially coplanar with the lower surface.

11. The method of claim 10, wherein removing excess material comprises thinning the substrate by also removing part of the substrate at the lower surface.

12. The method of claim 9, wherein filling the one or more cavities comprises:
covering the lower surface and the one or more cavities with the material to a thickness more than sufficient to fill the one or more cavities; and
removing excess material so that the exterior surface of the material is substantially planar and lies beyond the lower surface.

13. The method of claim 9, wherein the substrate is a semiconductor extending substantially from the upper to the lower surface.

14. The method of claim 9, wherein:
providing a substrate comprises, providing a composite substrate having a first semiconductor region proximate the upper surface containing the device region, a second semiconductor region proximate the lower surface, and an insulating layer located between the first and second semiconductor regions; and
etching one or more cavities comprises, etching one or more cavities extending from the lower surface underneath the device region through the second semiconductor region to the insulating layer.

15. A semiconductor device including an under-filled heat extractor, comprising:
a substrate having an upper surface and a lower surface and a semiconductor located proximate the upper surface with a device region therein;
one or more cavities formed in the substrate extending from the lower surface toward the upper surface and underlying the device region; and
a higher thermal conductivity material relative to the substrate, filling the one or more cavities and with an exposed surface underlying the device region at or below the lower surface, thereby forming the under-filled heat extractor.

16. The device of claim 15, wherein the exposed surface is substantially coplanar with the lower surface.

17. The device of claim 15, wherein the exposed surface is substantially planar and covers at least part of the lower surface.

18. The device of claim 17, wherein:
the substrate is a composite substrate with a first semiconductor region extending to the supper surface and containing the device region, a second semiconductor region extending to the lower surface and an insulating layer located between the first and second semiconductor regions; and
the one or more cavities extend from the lower surface to the insulating layer.

19. The device of claim 15, further comprising a heat sink in thermal contact with the under-filled heat extractor.

20. The device of claim 15, wherein the higher thermal conductivity material comprises copper, silver, aluminum, gold or other metals having a thermal conductivity larger than the semiconductor.
